(19) United States
(12) Patent Application Publication
(10) Pub. No.: US 2016/0072253 A1
(43) Pub. Date: Mar. 10, 2016

(54) DRIVER SYSTEM FOR SEMICONDUCTOR LASER EXCITED SOLID-STATE LASER

(71) Applicant: SHOWA OPTRONICS CO., LTD., Tokyo (JP)

(72) Inventor: Minoru KADOYA, Machida-shi (JP)

(21) Appl. No.: 14/663,048

(22) Filed: Mar. 19, 2015

(30) Foreign Application Priority Data
Sep. 9, 2014 (JP) 2014-182892

(51) Int. Cl. H01S 5/042; H01S 5/024; H01S 5/04

(52) U.S. Cl. CPC H01S 5/042; H01S 5/041; H01S 5/024

(57) ABSTRACT

The switching power source circuit (11) for the solid-state laser (100) excited by a semiconductor laser (101) uses a higher switching frequency than the relaxation oscillation (f_{RO}) of the solid-state laser so that the optical noises due to the switching noises or ripples in the output voltage of the switching power source circuit can be minimized. When the voltage drop caused by a semiconductor power device (Q2) is forwarded to a feedback terminal (11b) of the switching power source circuit, even when the forward voltage of the semiconductor laser should vary, the output voltage of the switching power source circuit can be regulated to a value suitable for the driving of the semiconductor laser, and the heat generation from the semiconductor power device can be minimized.

### CROSS-REFERENCE TO RELATED APPLICATION(S)

This application claims the benefit of and priority to Japanese Application No. 2014-182892 filed on Sep. 9, 2014, which is incorporated herein by reference in its entirety.

### TECHNICAL FIELD

The present invention relates to a driver system for a solid-state laser excited by a semiconductor laser, and in particular to a driver system for a solid-state laser that allows optical noises to be reduced and the conversion efficiency to be improved.

### BACKGROUND OF THE INVENTION

The lasers capable of operating continually in the visible light range, ultraviolet range and near infrared range and having a power output of less than 1 W which traditionally have been gas lasers are now being replaced by semiconductor lasers and solid-state lasers excited by semiconductor lasers. Such lasers are normally incorporated into testing, analyzing and measuring apparatuses, and are desired to be highly compact and low in power consumption.

Meanwhile, switching power sources are widely used in various fields because of the great freedom in converting AC current into DC current and DC current into DC current with a desired voltage conversion, and a high conversion efficiency. In the field of semiconductor lasers, it is known to use a switching power source in a part of a driver circuit of a semiconductor laser (See JP2005-349430A, for instance).

The inventor is not aware of any incidence of using a switching power source for a solid-state laser excited by a semiconductor laser, but it can be surmised that a switching power source would be suitable for powering a semiconductor laser and controlling an electronic cooling device used for temperature control in a solid-state laser excited by a semiconductor laser.

The voltage versus current property of a semiconductor laser is influenced by temperature, and the current changes significantly for a slight change in the voltage. Therefore, it is desirable in driving a semiconductor laser for exciting a solid-state laser to control the current either directly or indirectly such that the laser power stays at a certain output, instead of controlling the voltage. In such a current control, the laser power that is to be controlled may be either the output of the semiconductor laser or the output of the solid-state laser excited by the semiconductor laser. In a situation where a semiconductor laser is actively controlled by using a semiconductor power device for such a current control, even though the switching power source is able to provide a constant voltage at a high conversion efficiency, if there is any significant voltage drop in the semiconductor power device for the current control, the energy conversion efficiency of the solid-state laser excited by a semiconductor laser inevitably drops.

To overcome this problem, in the inventions disclosed in U.S. Pat. No. 8,571,079 and U.S. Pat. No. 7,978,743, the switching power source is controlled by taking into account the voltage information on the voltage drop in the semiconductor power device for the current control such that the voltage drop at the semiconductor power device for driving the semiconductor laser is minimized. In the conventional technologies disclosed in U.S. Pat. No. 8,571,079 and U.S. Pat. No. 7,978,743, the output voltage of the switching power source is controlled by using a pre-programmed micro-controller and a complex circuit called as a target controller, respectively.

In the driver circuit for a solid-state laser excited by a semiconductor laser, the switching power source presents another aspect that requires a special attention. The switching power source is generally configured to provide a constant voltage by controlling the ratio of the on period and the off period (duty ratio) of a switching device that is included in the switching power source (PWM: pulse width modulation). Therefore, the output voltage contains some ripples, instead of being a pure DC voltage. A smoothing circuit including a capacitor or an inductor is used for eliminating such ripples, but is unable to entirely remove the ripples so that a small amount of a ripple component at the frequency of the switching frequency inevitably remains. The switching frequency of the switching power sources typically ranges between several tens of kHz to several hundreds of kHz. The higher the switching frequency is, the better the smoothing circuit can remove the ripple component. However, a higher switching frequency means a higher rate of transition between the on and off states of the switching device, and this in turn causes a greater loss or a lower conversion efficiency. Thus, there is a tradeoff between the minimization of ripples and the maximization of the conversion efficiency in selecting the switching frequency of a switching power source.

The laser, be it a semiconductor laser or a solid-state laser, has a frequency property having a peak modulation sensitivity at an intrinsic frequency known as the relaxation oscillation frequency. In the case of a solid-state laser excited by a semiconductor laser, it is known that the relaxation oscillation frequency f_{RO} can be obtained from Equation (1) given in the following (See Amnon Yariv, “Quantum Electronics”, 3rd ed., John Wiley & Sons, Inc., Chapter 20.4, 1989, for instance).

$${f}_{RO} = \frac{1}{2 π} \sqrt{\frac{1}{{τ}_{c} {τ}_{f}} ( r - 1 )} \qquad ( 1 )$$

where τ_{c} is the photon decay rate, τ_{f} is the upper energy level decay rate of active ions, r is the excitation ratio (or the ratio of the excitation optical power Pop during operation to the threshold value Pth of the laser oscillation excitation power).

In the case of a solid-state laser involving the generation of the intracavity second-order harmonic, the relaxation oscillation frequency f_{RO} computed by Equation (1) is closer to the actually measured value if the threshold value Pth computed as given in the following is used, instead of the actual threshold value Pth0 which is an extremely small value, for the computation of the excitation value. FIG. 4 is a graph showing the relationship between the excitation optical power and the second-order harmonic power in which the abscissa is the excitation optical power, and the ordinate is the second-order harmonic power. Suppose that the desired second-order harmonic power is obtained at the operating point A. The intersection of the tangent line at the operating point A with the abscissa is deemed as the oscillation threshold value Pth, and the excitation ratio r is computed as the ratio of the excitation optical power Pop at the operating point A to the oscillation threshold value Pth (or Pop/Pth). This provides a relaxation oscillation frequency f_{RO} which is closer to the actually measured value than using the actual threshold value Pth0.

The relaxation oscillation frequency f_{RO} is computed in the following by using the threshold value as discussed above. In this example, the laser system consists of a solid-state laser excited by a semiconductor laser which is known as an intracavity second-order harmonic laser and includes a laser gain medium (solid laser crystal) (consisting of) Nd:YAG or Nd:YVO₄ and a nonlinear optical crystal received in a resonating cavity for intracavity second-harmonic generation.

The value of the photon decay rate τ_{c} is based on a resonating cavity having a cavity length of 20 mm to 100 mm and a resonator loss of 1% including that of the output coupling. The cavity length is measured by taking into account the refractive indices of the optical components in the cavity. The excitation ratio r is limited to the range of 1.5 to 3.0 in view of the fact that the laser is based on intracavity second-harmonic generation. The relaxation oscillation frequency f_{RO} that is obtained under such conditions is in the range of about 30 kHz to 200 kHz.

The modulation frequency property or the relationship of the modulation sensitivity of the output optical power to the modulation frequency f of the excitation light for lasers in general, including solid-state lasers excited by a semiconductor laser can be obtained from Equation (2) given in the following. Equation (2) is given in the aforementioned literature with some change in the notation of variables (t_{c} and τ are changed to τ_{c} and τ_{f}), respectively.

$$Q ( ω ) = \frac{- \frac{1}{{τ}_{c}} ( r - 1 ) R ( ω )}{{ω}^{2} - i \frac{r}{{τ}_{c}} ω - \frac{1}{{τ}_{c} {τ}_{f}} ( r - 1 )} \qquad ( 2 )$$

In Equation (2), ω=2πf. Q(ω) and R(ω) are functions obtained by Fourier conversion of the time functions of the photon density in the resonating cavity and the excitation rate, respectively. The transfer function can be represented by Equation (3) given in the following.

$$H ( ω ) = \frac{Q ( ω )}{R ( ω )} \qquad ( 3 )$$

In the graph of FIG. 5, the abscissa represents the normalized frequency f/f_{RO} (the ratio of the modulation frequency f to the relaxation oscillation frequency f_{RO}), and ordinate represents the modulation sensitivity (the ratio of the output optical power variation to the excitation optical power variation which is normalized by the value in the low frequency range) as given by Equation (4) below.

$$modulation sensitivity = \vert \frac{Q ( f )}{R ( f )} \vert + \vert \frac{Q ( 0 )}{R ( 0 )} \vert \qquad ( 4 )$$

The results shown in FIG. 5 are obtained when the upper energy level decay rate τ_{f} is 90 μsec, the excitation ratio r is 2 and the photon decay rate τ_{c} is a value obtained with the intracavity loss of 1% and the resonating cavity length of 20 mm. In this case, the relaxation oscillation frequency f_{RO} that can be obtained from Equation (1) is about 200 kHz. When the excitation optical power is modulated at a frequency substantially lower than this frequency, the output optical power changes in dependence on the excitation optical power (or the modulation sensitivity is substantially constant). However, when the modulation frequency f is in the range of 0.3 to 1.5 times the relaxation oscillation frequency f_{RO}, the modulation sensitivity changes from about one to several tens. In other words, near the relaxation oscillation frequency f_{RO}, the variation of the output optical power for a given variation of the excitation optical power is great.

Because the switching frequency of a switching power source is typically in the range of tens of kHz to hundreds of kHz as discussed above, the switching frequency could be near the relaxation oscillation frequency f_{RO} (about 200 kHz) or may fall in the range of 0.3 to 1.5 times of the relaxation oscillation frequency f_{RO}. In particular, in an intracavity second-order harmonic laser, the relaxation oscillation frequency f_{RO} (30 kHz to 200 kHz) at which the modulation sensitivity is the highest may coincide with the switching frequency of the switching power source. Therefore, if the laser power of the semiconductor laser used for exciting a solid-state laser is modulated by the current ripples corresponding to the switching frequency of the switching power source, the output light of the solid-state laser excited by the semiconductor laser may be contaminated by significant optical noises.

Even when the optical noise may not be significant at a certain laser power, if the laser power (excitation optical power) of the semiconductor laser for excitation is changed, the excitation ratio r in Equation (1) changes, and the relaxation oscillation frequency f_{RO} (at which the modulation sensitivity is high) may coincide with the switching frequency or any harmonic thereof so that the optical noises may become unacceptably high. In particular, the speed of switching devices is being improved to such an extent that the transition time period between on and off states can be made shorter than was possible with the more conventional switching devices without lowering the conversion efficiency of the switching device.

### SUMMARY OF THE INVENTION

The present invention was made in view of such problems of the prior art, and has a primary object to provide a driver system for a solid-state laser excited by a semiconductor laser that can minimize optical noises due to the switching action of the switching power source circuit while achieving a high energy conversion efficiency.

A second object of the present invention is to provide a driver system for a solid-state laser excited by a semiconductor laser that can minimize optical noises due to the switching action of the switching power source circuit by using a highly simple control arrangement.

The present invention achieves such objects by providing a driver system (10) for a solid-state laser (100) excited by a semiconductor laser (101), comprising: a switching power source circuit (11) for converting externally supplied electric power of a certain voltage into DC power of a prescribed voltage; and a semiconductor laser driver circuit (12) powered by the switching power source circuit for driving the semiconductor laser for exciting the solid-state laser; wherein the switching power source circuit uses a switching frequency at least twice, preferably at least ten times of a relaxation oscillation frequency of the solid-state laser.

According to this arrangement, not only the benefit of the high power conversion efficiency of the switching power source circuit can be obtained but also the optical noises of the sold-state laser can be minimized without requiring any complex or expensive arrangement. More specifically, even when the output of the solid-state laser is contaminated by the noises due to the ripples contained in the electric power supplied by the switching power source circuit, because the frequency of the ripple component is substantially higher than the relaxation oscillation frequency f_{RO} of the solid-state laser, the modulation sensitivity of the solid-state laser is minimized, and this causes the optical noises to be minimized. In a typical solid-state laser excited by a semiconductor laser, the switching frequency of the switching power source circuit is preferably 2 MHz or higher because the relaxation oscillation frequency is approximately 200 kHz or lower.

The present invention may also provide a laser system including a solid-state laser (100) excited by a semiconductor laser (101), comprising: a switching power source circuit (11) for converting externally supplied electric power of a certain voltage into DC power of a prescribed voltage; and a semiconductor laser driver circuit (12) powered by the switching power source circuit for driving the semiconductor laser for exciting the solid-state laser; wherein the switching power source circuit uses a switching frequency at least twice, preferably at least ten times of a relaxation oscillation frequency of the solid-state laser.

According to this arrangement, not only the benefit of the high power conversion efficiency of the switching power source circuit can be obtained but also the optical noises of the sold-state laser can be minimized without requiring any complex or expensive arrangement. More specifically, even when the output of the solid-state laser is contaminated by the noises due to the ripples contained in the electric power supplied by the switching power source circuit, because the frequency of the ripple component is substantially higher than the relaxation oscillation frequency of the solid-state laser, the modulation sensitivity of the solid-state laser is minimized, and this causes the optical noises to be minimized. In a typical solid-state laser excited by a semiconductor laser, the switching frequency of the switching power source circuit is preferably 2 MHz or higher because the relaxation oscillation frequency is approximately 200 kHz or lower.

According to a preferred embodiment of the present invention, the switching power source circuit is provided with a feedback input terminal for output voltage control thereof, and the driver circuit comprises a semiconductor power device for controlling current supplied to the semiconductor laser, a node between the semiconductor power device and the semiconductor laser being connected to the feedback input terminal.

Thereby, even when the voltage drop of the semiconductor power device for current control is relatively small, any variation in the voltage drop can be offset or compensated by the corresponding change in the output voltage of the switching power source circuit owing to the feedback action provided by the feedback input terminal. Also, even when the forward voltage of the semiconductor laser should change owing to the changes in the property of the semiconductor laser, the switching power source circuit can actively adjust the output voltage thereof such that the increase in the voltage drop and hence the heat generation of the semiconductor power device for the semiconductor laser can be minimized.

The switching power source circuit for the solid-state laser excited by a semiconductor laser uses a higher switching frequency than the relaxation oscillation of the solid-state laser so that the optical noises due to the switching noises or ripples in the output voltage of the switching power source circuit can be minimized. When the voltage drop caused by a semiconductor power device is forwarded to a feedback terminal of the switching power source circuit, even when the forward voltage of the semiconductor laser should vary, the output voltage of the switching power source circuit can be regulated to a value suitable for the driving of the semiconductor laser, and the heat generation from the semiconductor power device can be minimized. Thus, according to the present invention, not only the benefit of the high power conversion efficiency of the switching power source circuit can be obtained but also the optical noises of the sold-state laser can be minimized without requiring any complex or expensive arrangement.

### BRIEF DESCRIPTION OF THE DRAWINGS

Now the present invention is described in the following with reference to the appended drawings, in which:

FIG. 1 is a circuit diagram of a solid-state laser excited by a semiconductor laser given as a first embodiment of the present invention;

FIG. 2 is a schematic diagram illustrating the structure of the solid-state laser excited by a semiconductor laser;

FIG. 3 is a circuit diagram of a second embodiment of the present invention;

FIG. 4 is a graph showing the relationship between the excitation optical power and the second-order harmonic power; and

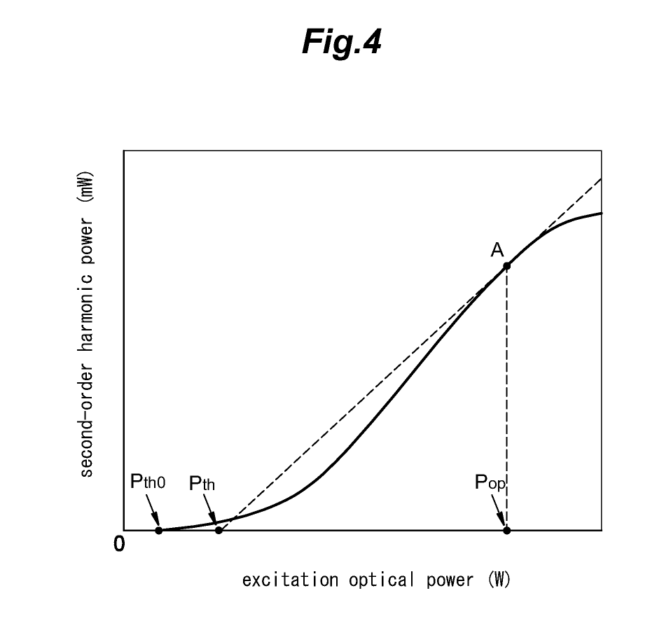

FIG. 5 is a graph showing the frequency property of the modulation sensitivity of the solid-state laser.

### DESCRIPTION OF THE PREFERRED EMBODIMENT(S)

### First Embodiment

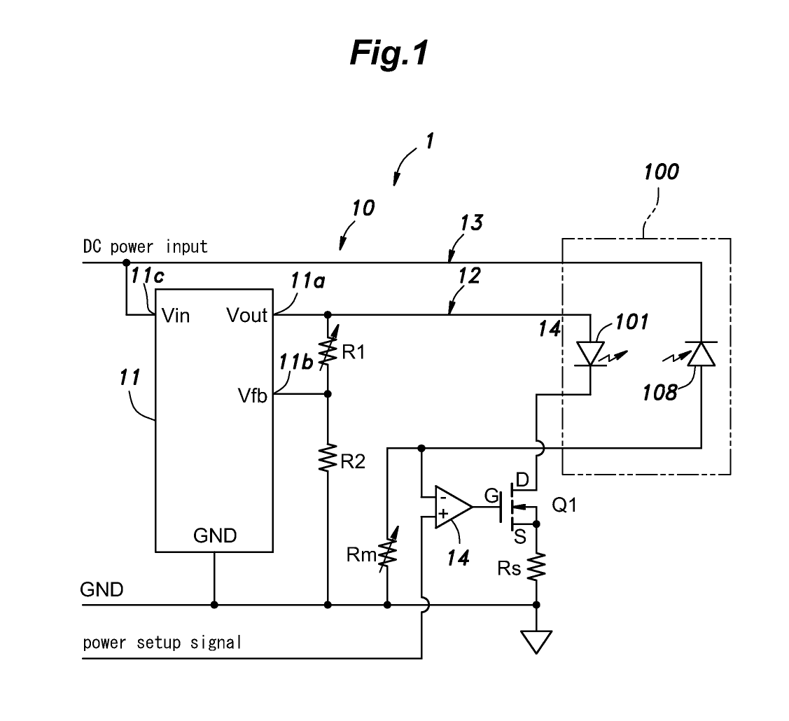

FIG. 1 is a circuit diagram of a laser system 1 including a solid-state laser 100 incorporated with a semiconductor laser 101 for exciting the solid-state laser 100 given as a first embodiment of the present invention. The laser system 1 further comprises a driver circuit 10 for driving the semiconductor laser 101 that is used for exciting the solid-state laser 100. The laser system 1 normally includes a temperature control circuit for controlling the temperature of the solid-state laser 100, but the temperature control circuit is omitted in FIG. 1 as it is not essential for the present invention.

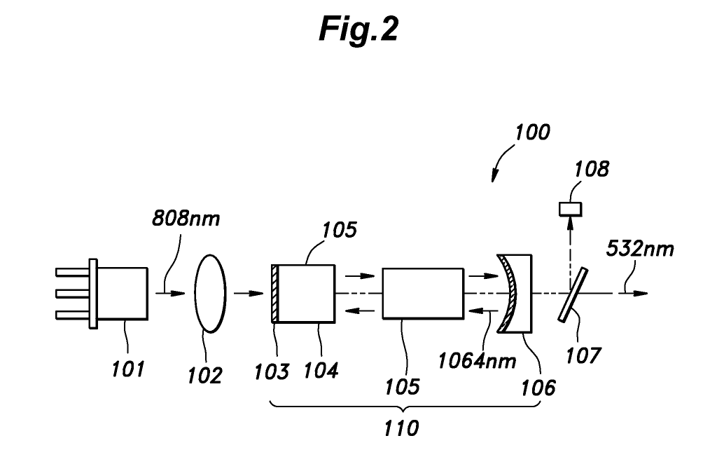

Referring to FIG. 2, the solid-state laser 100 additionally includes a condenser lens 102 consisting of an aspheric lens for condensing the laser light emitted from the semiconductor laser 101, a laser crystal 104 provided with a first reflective mirror 103 (consisting of a dielectric multilayer film) on a surface thereof facing the condenser lens 102 and configured to be optically excited by the laser light (emitted from the semiconductor laser 101) transmitted through the condenser lens 102, a nonlinear optical crystal 105 for generating a second-order harmonic from the laser light exiting from the laser crystal 104, a second reflective mirror 106 opposing the side of the nonlinear optical crystal 105 facing away from the laser crystal 104, a beam splitter 107 for splitting a part of the output light transmitted through the second reflective mirror 106 for laser power monitoring, and a photodiode 108 for detecting the output power of the laser light split by the beam splitter 107. The laser crystal 104 uses Nd:YVO₄ for the laser gain medium thereof, and forms a laser resonator 110 in cooperation with the optical elements arranged between the first reflective mirror 103 and the second reflective mirror 106.

In the solid-state laser 100, an oscillation with a wavelength of 1,064 nm is caused in the laser crystal 104 by an excitation by the semiconductor laser 101 having a laser wavelength of 808 nm, and the laser light of the second-order harmonic with a wavelength of 532 nm created by the wavelength conversion in the nonlinear optical crystal 105 is emitted from the laser resonator 110 as output. The laser power output of the solid-state laser 100 is 200 mW when the semiconductor laser 101 is operated with a forward voltage of approximately 1.9 V and a maximum current of approximately 2 A, and the relaxation frequency f_{RO} under this operating condition is approximately 200 kHz.

Referring to FIG. 1 once again, the driver circuit 10 includes a switching power source circuit 11 for converting externally supplied electric power into DC electric power of a prescribed voltage Vout, and a semiconductor laser driver circuit 12 powered by the switching power source circuit 11 for driving the semiconductor laser 101. In FIG. 1, the semiconductor laser 101 and the photodiode 108 that are necessary for the description of the operation of the semiconductor laser driver circuit 12 are illustrated, but the laser crystal 104 and the other optical elements are omitted from the drawing.

The switching power source circuit 11 may consist of a per se known switching power source circuit such as a circuit formed by using LTC 3616 which is a DC/DC converter IC manufactured by Linear Technology of the United States, and may include other circuit elements for setting and controlling the parameters for the operation of this IC and a smoothing circuit for reducing ripples in the output. More specifically, the switching power source circuit 11 may be essentially the same as the standard circuit described in the datasheet “LTC3616 6A, 4 MHz Monolithic Synchronous Step-Down DC/DC Converter”, (LT 1133 Rev. B, 2010) supplied by the manufacturer of the IC. As the structure of the switching power source circuit 11 is per se known, any detailed description of the structure thereof is omitted in the following description.

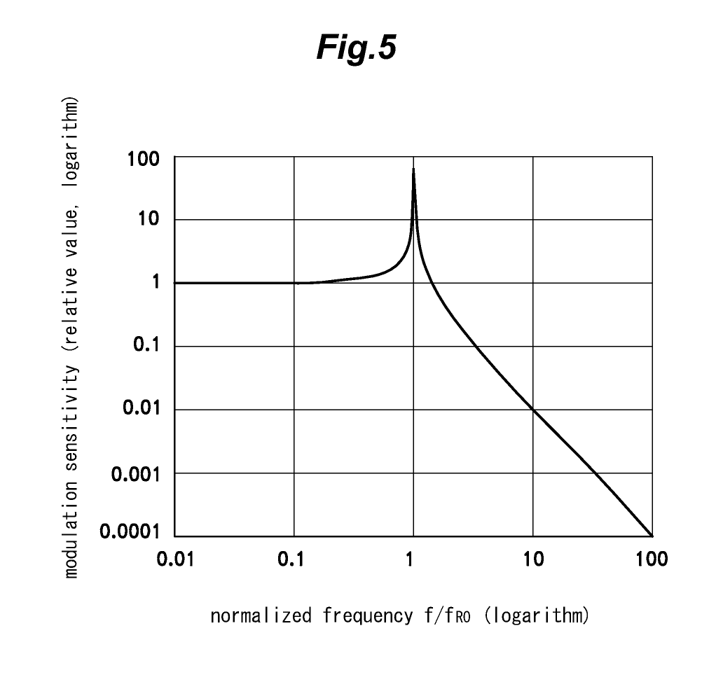

This switching power source circuit 11 allows the switching frequency to be varied between 1 MHz and 4 MHz by adjusting an external resistor not shown in the drawings. The modulation frequency response of the laser crystal 104 is shown in FIG. 5, and it can be seen that the modulation sensitivity is inversely proportional to the square of the frequency when the modulation frequency is higher than twice the relaxation oscillation frequency f_{RO}. When the switching frequency is higher than ten times the relaxation oscillation frequency f_{RO}, the modulation sensitivity of the laser crystal 104 is less than one hundredth so that even when the output voltage Vout of the switching power source circuit 11 contains a significant amount of ripples, the optical noises in the output of the solid-state laser 100 due to the ripples are expected to be negligibly small. As discussed above, the upper limit of the variable range of the relaxation oscillation frequency f_{RO} that can be varied depending on the operating point (or the output) of solid-state laser 100 is about 200 kHz, and the relaxation oscillation frequency f_{RO} of the laser crystal (Nd:YVO₄ crystal) is also about 200 kHz. In this embodiment, the switching frequency of the switching power source circuit 11 is set at 2.6 MHz that is more than ten times greater than 200 kHz with some safety margin.

The switching power source circuit 11 receives DC electric power having a voltage of 5 V from an external source, and converts this voltage to a prescribed DC output voltage Vout. The switching power source circuit 11 is able to supply electric current in excess of 2 A. The output terminal 11a of the switching power source circuit 11 is connected to the anode of the semiconductor laser 101. The output voltage Vout produced from an output terminal 11a of the switching power source circuit 11 is also divided by a variable resistor R1 and a fixed resistor R2, and the divided voltage is supplied to a feedback input terminal 11b of LTC3616 (DC/DC converter IC) to be monitored as a feedback voltage Vfb and compared with an internal reference voltage (0.6 V in this case) of the IC. The switching power source circuit 11 decreases the output voltage Vout when the feedback voltage Vfb is higher than 0.6V, and increases the output voltage Vout when the feedback voltage Vfb is lower than 0.6V. Thus, the value of the output voltage Vout can be given as a mathematical function of the variable resistor R1 and the fixed resistor R2 as expressed by Equation (5) given below.

Vout=0.6{1+(R1/R2)} (5)

The electric current that flows out or into the feedback input terminal 11b is less than 30 nA according to the data sheet mentioned above. The value of the resistor R2 is set at 100 kΩ so that the setting of the voltage may not be affected by this current. When the value of the variable resistor R1 is selected as 400 kΩ, the output voltage Vout is about 3.0 V.

The semiconductor power device that is incorporated in the semiconductor laser driver circuit 12 to control the current flowing through the semiconductor laser 101 consists of a MOS field effect transistor (MOSFET) in the illustrated embodiment, but a bipolar transistor may also be used instead. In this embodiment, the MOSFET (Q1) consists of 2SK2937 manufactured by Renesas Electronics KK of Japan. The MOSFET (Q1) is connected between the cathode of the semiconductor laser 101 and ground GND. In order for the MOSFET (Q1) to operate in an unsaturated region, the drain-source voltage VDS may be about 0.5 V. The output voltage Vout of the switching power source circuit 11 is selected such that the drain-source voltage VDS is about 1.0 V at the maximum current of 2 A, and possible variations in the forward voltage of the semiconductor laser 101 may be accommodated. When the drain current is at the maximum value of 2 A, the MOSFET (Q1) produces heat of about 2 W. Therefore, the MOSFET (Q1) is attached to a metallic case (not shown in the drawings) external to the circuit board so that this heat may be favorably dissipated.

The photodiode 108 is incorporated in a laser power monitor circuit 13 that is connected between the DC power source for supplying the input voltage Vin to the input terminal 11c of the switching power source circuit 11 and the ground GND end of the MOSFET (Q1) in the semiconductor laser driver circuit 12. The photodiode 108 produces photocurrent which corresponds to the laser power of the solid-state laser 100.

A resistor Rs having a value of 50 mΩ is connected between the MOSFET (Q1) and ground GND in the semiconductor laser driver circuit 12 for monitoring the electric current conducted by the MOSFET (Q1). The voltage across this resistor Rs is monitored by a monitoring circuit not shown in the drawings so that the maximum current that flows into the semiconductor laser 101 may be limited. A resistor Rm for monitoring laser power consists of a variable resistor of 10 kΩ, and is connected between the photodiode 108 and ground GND in the laser power monitor circuit 13. A voltage is produced across this resistor Rm by the photocurrent produced from the photodiode 108, and the voltage at the end of this resistor Rm opposite from the GND end provides a laser power monitor value.

The semiconductor laser driver circuit 12 includes an operational amplifier 14 having an output terminal that is connected to the gate terminal G of the MOSFET (Q1). The operational amplifier compares the laser power monitor value and a power setup signal value indicating a preset value of the laser power that are supplied thereto, and controls the MOSFET (Q1) such that the current flowing into the semiconductor laser 101 is increased when the laser power monitor value is lower than the power setup signal value, and is decreased when the laser power monitor value is higher than the power setup signal value.

The solid-state laser 100 is driven by this semiconductor laser driver circuit 12, and optical noises were measured by using a measuring system having signal bandwidth of 100 MHz. The optical noise level was about 0.1% rms, and this level is low enough to be acceptable in most applications. When the power setup signal value was changed to adjust the laser power of the solid-state laser 100, a small increase in the noise level was observed near the laser oscillation threshold value of the laser crystal 104, but no increase in the noise level due to the relaxation oscillation near the relaxation oscillation frequency f_{RO} was detected. When the anode of the semiconductor laser 101 was connected to a +5V DC power source, the power source efficiency was 38% whereas the power efficiency of the arrangement illustrated in FIG. 1 was 57%.

### Second Embodiment

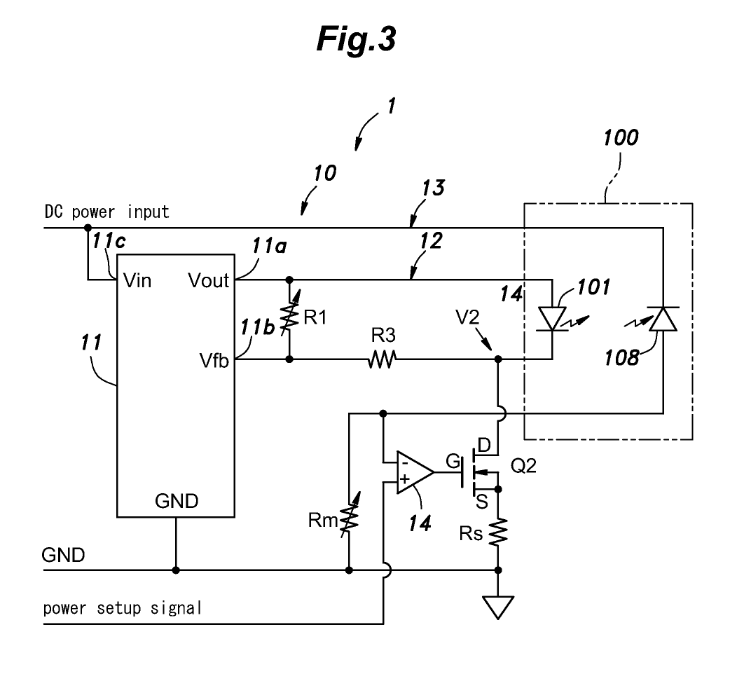

FIG. 3 is a circuit diagram of a laser system 1 given as a second embodiment of the present invention. The structure of the solid-state laser 100 of the second embodiment is no different from that of the first embodiment (FIG. 2), and the details thereof are omitted in the following description. The parts of the second embodiment corresponding to those of the first embodiment are denoted with like numerals without necessarily repeating the description of such parts.

The second embodiment is different from the first embodiment in the following respect. The MOSFET (Q2) consists of IRF7401 manufactured by International Rectifier of the United States. The 100 kΩ resistor R2 is omitted, and, instead, a 10 kΩ resistor R3 is connected to a node between the feedback input terminal 11b of the switching power source circuit 11 for voltage monitoring and the drain D (at a drain voltage V2 as indicated by an arrow in FIG. 3) of the MOSFET (Q2). The variable resistor R1 is configured to be variable in a range around 85 kΩ.

The MOSFET (Q2) is configured to be surface-mounted on a circuit board, and preferably emits heat of less than 1 W in view of the possible use in high temperature environments. Therefore, the drain-source voltage VDS is required to be no more than 0.5 V, preferably no more than 0.4 V when electric current of 2 A is conducted. In order for the MOSFET (Q2) to operate in a non-saturated region with a reasonable margin when the drain current is 2 A, the drain-source voltage VDS should be 0.2V or higher. Hence, the tolerable range of the drain-source voltage VDS is between 0.2 V and 0.4 V.

In order to maintain the drain-source voltage VDS within this narrow range, the resistor R3 is added, and the value of the variable resistor R1 is modified. How the values of these resistors are determined is discussed in the following. In a standard condition, a maximum current of 2 A is fed to the semiconductor laser 101. Suppose that the drain-source voltage VDS is at 0.3 V or a middle point of the tolerable range. The voltage drop across the current monitoring resistor Rs is 0.1 V, and the voltage drop across the semiconductor laser 101 is 1.9 V. When these voltage drops are considered, it can be seen that the drain voltage V2 at the node between the cathode of the semiconductor laser 101 and the resistor R3 is required to be 0.4 V, and the output voltage Vout of the switching power source circuit 11 is required to be 2.3 V. Based on the balance of electric current that flows into and flows out of the node between the variable resistor R1 and the resistor R3, Equation (6) given in the following can be obtained.

(Vₒᵤₜ−V_{fb})/R₁=(V_{fb}−V₂)/R₃ (6)

The electric current that flows into the feedback input terminal 11b is disregarded in this case. The values in Equation (6) other than the values of the variable resistor R1 and the resistor R3 are all determined or fixed, and only the ratio of the variable resistor R1 and the resistor R3 is of consequence in Equation (6). Therefore, there are an infinite number of combinations of the values of R1 and R3. In this case, the variable resistor R1 and the resistor R3 are selected at 85 kΩ and 10 kΩ, respectively, such that the current that flows through the variable resistor R1 and the resistor R3 is sufficiently greater than the current that flows into the feedback input terminal 11b, and sufficiently smaller than the current that is supplied to the semiconductor laser 101. However, as long as the ratio of the values of these resistors R1 and R3 is maintained, these values may be freely selected such as to be 10 times greater and ten times smaller, for instance.

By selecting the values of the variable resistor R1 and the resistor R3 as discussed above, even when the drain-source voltage VDS of the MOSFET (Q2) has increased, and the drain voltage V2 of the MOSFET (Q2) has increased, the resulting increase of the voltage Vfb at the feedback input terminal 11b of the switching power source circuit 11 from 0.6 V is offset by the drop in the output voltage Vout of the switching power source circuit 11. Conversely, if the drain voltage V2 of the MOSFET (Q2) has decreased, the output voltage Vout of the switching power source circuit 11 is increased by a corresponding amount.

The solid-state laser 100 excited by a semiconductor laser was operated with the values and parameters discussed above. When electric current of 2 A was supplied to the semiconductor laser 101, the solid-state laser 100 operated substantially as initially designed. The heat generation from the MOSFET (Q2) was 0.6 W, and was small enough for the MOSFET (Q2) to be surface-mounted without any problem. When the current of the semiconductor laser 101 was gradually reduced from 2 A, the drain-source voltage VDS progressively increased, and eventually exceeded the target voltage range. However, the heat generation from the MOSFET (Q2) decreased to a value substantially lower than the tolerable range. For instance, when the current supplied to the semiconductor laser 101 was about 10 mA, the drain-source voltage VDS of the MOSFET (Q2) was 0.44 V which was higher than the target range of 0.4 V. The heat generation at this time was about 4 mW (by computation).

Because the forward voltage of the semiconductor laser 101 does not distinctly changes as long as the semiconductor laser 101 is operated at a constant temperature, the change in the property of the semiconductor laser 101 owing to the degradation thereof over time was simulated as described in the following.

Instead of the semiconductor laser 101, a pair of silicon diodes each demonstrating a forward voltage of about 0.8 V with a forward current of 2 A and a Schottky barrier diode demonstrating a forward voltage of about 0.4 V with a forward current of 2 A, all connected in series, were used as the load of the switching power source circuit. In the circuit shown in FIG. 3, the photodiode 108 connected to the inverting input of the operational amplifier 14 was temporarily disconnected, and the positive end of the current monitoring resistor Rs was connected to the inverting input of the operational amplifier 14, instead of the laser power monitoring signal while an appropriate signal was supplied to the non-inverting input of the operational amplifier 14 so that the constant current of 2 A was maintained.

By short-circuiting the two ends of the Schottky barrier diode, the forward voltage of the load was changed from about 2V to 1.6 V. This short-circuiting did not cause any change in the electric current supplied to the load while the drain-source voltage VDS changed from 0.28 V to 0.33 V. The heat generation only slightly increased from 0.54 W to 0.66 W. The output voltage Vout of the switching power source circuit 11 changed from 2.43 V to 2.07 V. The increase in the heat generation of the MOSFET (Q2) was mere 0.1 W. Whereas the power source efficiency when the anode of the semiconductor laser 101 was connected to a DC power source of +5 V was 38%, the arrangement shown in FIG. 3 achieved a significantly higher power source efficiency of 74%.

If the switching power source circuit 11 is not provided with the function to actively change the output voltage Vout thereof, the drop in the forward voltage of 0.4 V caused by the short-circuiting causes an increase in the voltage drop across the MOSFET (Q2). This will cause an increase in the generation of heat from 0.54 W to an unacceptable value of 1.34 W. According to the illustrated embodiment, the heat generation can be minimized even when the operating condition is changed significantly so that a surface-mount type semiconductor device (Q2) which is mounted on the circuit board without any special heat dissipation arrangement can be used without any problem.

In the forgoing embodiments, the switching power source circuit 11 consisted of a DC/DC converter, but may also consist of an AC/DC converter. The MOSFET that was used for controlling the current supplied to the semiconductor laser 101 in the foregoing embodiments may be substituted by a bipolar transistor. The solid-state laser 100 in the foregoing embodiments consisted of Nd:YVO4 solid-state laser based on intracavity second-order harmonic generation, but may also use other gain media and/or may not involve frequency conversion.

Although the present invention has been described in terms of preferred embodiments thereof, it is obvious to a person skilled in the art that various alterations and modifications are possible without departing from the scope of the present invention which is set forth in the appended claims. The contents of the original Japanese patent application on which the Paris Convention priority claim is made for the present application as well as the contents of the prior art references mentioned in this application are incorporated in this application by reference.

1. A driver system for a solid-state laser excited by a semiconductor laser, comprising:
a switching power source circuit for converting externally supplied electric power of a certain voltage into DC power of a prescribed voltage; and
a semiconductor laser driver circuit powered by the switching power source circuit for driving the semiconductor laser for exciting the solid-state laser;
wherein the switching power source circuit uses a switching frequency at least twice a relaxation oscillation frequency of the solid-state laser.

2. The driver system for the solid-state laser excited by the semiconductor laser according to claim 1, wherein the switching frequency of the switching power source circuit is at least ten times of the relaxation oscillation frequency of the solid-state laser.

3. The driver system for the solid-state laser excited by the semiconductor laser according to claim 1, wherein the switching frequency of the switching power source circuit is 2 MHz or higher.

4. The driver system for the solid-state laser excited by the semiconductor laser according to claim 1, wherein the switching power source circuit is provided with a feedback input terminal for output voltage control thereof, and the semiconductor laser driver circuit comprises a semiconductor power device for controlling current supplied to the semiconductor laser, a node between the semiconductor power device and the semiconductor laser being connected to the feedback input terminal.
